(19) United States
(12) Patent Application Publication
(10) Pub. No.: US 2022/0375805 A1
(43) Pub. Date: Nov. 24, 2022

(54) TEST STRUCTURE OF INTEGRATED CIRCUIT

(71) Applicant: CHANGXIN MEMORY TECHNOLOGIES, INC., Hefei City (CN)

(72) Inventor: Qian XU, Hefei City (CN)

(21) Appl. No.: 17/659,056

(22) Filed: Apr. 13, 2022

(30) Foreign Application Priority Data
May 19, 2021 (CN) 202110545588.9

(51) Int. Cl. H01L 21/66

(52) U.S. Cl. CPC H01L 22/34

(57) ABSTRACT

The present disclosure relates to the technical field of integrated circuits, and provides a test structure of an integrated circuit, to solve the technical problem of difficulty in measuring electrical parameters of the integrated circuit. The test structure of an integrated circuit includes: a first P-type heavily doped region, a second P-type heavily doped region, and an N-type heavily doped region. There is a first distance between the first P-type heavily doped region and the second P-type heavily doped region, and there is a second distance between the second P-type heavily doped region and the N-type heavily doped region. Electrical parameters of the integrated circuit are obtained by adjusting at least one of the first distance and the second distance.

### CROSS-REFERENCE TO RELATED APPLICATION

This application claims the priority of Chinese Patent Application No. 202110545588.9, submitted to the Chinese Intellectual Property Office on May 19, 2021, the disclosure of which is incorporated herein in its entirety by reference.

### TECHNICAL FIELD

The present disclosure relates to the technical field of integrated circuits, and in particular, to a test structure of an integrated circuit.

### BACKGROUND

Harm caused by electrostatic discharge (ESD) to an electronic device, especially to an integrated circuit, has attracted increasing attention. In the case of electrostatic discharge, a large voltage is applied to an integrated circuit, to trigger a latch-up in the integrated circuit, resulting in a sudden and violent voltage snapback phenomenon. Such phenomenon usually affects the stability of the integrated circuit or even damage the integrated circuit.

To ensure the reliability of the integrated circuit, it is necessary to test electrical parameters of the integrated circuit when the latch-up occurs, so as to help design of the integrated circuit.

### SUMMARY

According to a first aspect, an embodiment of the present disclosure provides a test structure of an integrated circuit, including: a first P-type heavily doped region, a second P-type heavily doped region, and an N-type heavily doped region, where the first P-type heavily doped region, the second P-type heavily doped region, and the N-type heavily doped region are all located in an N well, and the N well is located on a P-type substrate; and there is a first distance between the first P-type heavily doped region and the second P-type heavily doped region, there is a second distance between the second P-type heavily doped region and the N-type heavily doped region, and electrical parameters of the integrated circuit are obtained by adjusting the first distance and/or the second distance.

According to a second aspect, an embodiment of the present disclosure provides a test structure of an integrated circuit, including: a first P-type heavily doped region, a second P-type heavily doped region, and an N-type heavily doped region, where the first P-type heavily doped region is located on a P-type substrate, the second P-type heavily doped region and the N-type heavily doped region are both located in an N well, and the N well is located on the P-type substrate; and there is a first distance between the first P-type heavily doped region and the second P-type heavily doped region, there is a second distance between the second P-type heavily doped region and the N-type heavily doped region, and electrical parameters of the integrated circuit are obtained by adjusting the first distance and/or the second distance.

According to a third aspect, an embodiment of the present disclosure provides a test structure of an integrated circuit, including: a first P-type heavily doped region, a second P-type heavily doped region, and an N-type heavily doped region, where the first P-type heavily doped region, the second P-type heavily doped region, and the N-type heavily doped region are all located in a deep N well, and the deep N well is located on a P-type substrate; the first P-type heavily doped region is located in a first P well, and the first P well is located in the deep N well; and/or, the second P-type heavily doped region is located in a second P well, and the second P well is located in the deep N well; and there is a first distance between the first P-type heavily doped region and the second P-type heavily doped region, there is a second distance between the second P-type heavily doped region and the N-type heavily doped region, and electrical parameters of the integrated circuit are obtained by adjusting the first distance and/or the second distance.

According to a fourth aspect, an embodiment of the present disclosure provides a test structure of an integrated circuit, including: a first P-type heavily doped region, a second P-type heavily doped region, and an N-type heavily doped region, where the first P-type heavily doped region is located on a P-type substrate, the second P-type heavily doped region is located in a P well that is located in a deep N well, the N-type heavily doped region is located in the deep N well, and the deep N well is located on the P-type substrate; and there is a first distance between the first P-type heavily doped region and the second P-type heavily doped region, there is a second distance between the second P-type heavily doped region and the N-type heavily doped region, and electrical parameters of the integrated circuit are obtained by adjusting the first distance and/or the second distance.

According to a fifth aspect, an embodiment of the present disclosure provides a test structure of an integrated circuit, including: a first P-type heavily doped region, a second P-type heavily doped region, and an N-type heavily doped region, where the first P-type heavily doped region is located on a P-type substrate, the second P-type heavily doped region and the N-type heavily doped region are both located in a deep N well, and the deep N well is located on the P-type substrate; and there is a first distance between the first P-type heavily doped region and the second P-type heavily doped region, there is a second distance between the second P-type heavily doped region and the N-type heavily doped region, and electrical parameters of the integrated circuit are obtained by adjusting the first distance and/or the second distance.

### BRIEF DESCRIPTION OF THE DRAWINGS

To describe the technical solutions in the embodiments of the present disclosure or in the prior art more clearly, the following briefly describes the accompanying drawings required for describing the embodiments or the prior art. Apparently, the accompanying drawings in the following description show some embodiments of the present disclosure, and a person of ordinary skill in the art may still derive other drawings from these accompanying drawings without creative efforts.

FIG. 1 is a schematic diagram of an application scenario of a test structure of an integrated circuit according to an embodiment of the present disclosure;

FIG. 2 is a top view of a first test structure of an integrated circuit according to an embodiment of the present disclosure;

FIG. 3 is a cross-sectional view of a first test structure of an integrated circuit according to an embodiment of the present disclosure;

FIG. 4 is a top view of a second test structure of an integrated circuit according to an embodiment of the present disclosure;

FIG. 5 is a cross-sectional view of a second test structure of an integrated circuit according to an embodiment of the present disclosure;

FIG. 6 is a top view of a third test structure of an integrated circuit according to an embodiment of the present disclosure;

FIG. 7 is a cross-sectional view of a third test structure of an integrated circuit according to an embodiment of the present disclosure;

FIG. 8 is a top view of a fourth test structure of an integrated circuit according to an embodiment of the present disclosure;

FIG. 9 is a cross-sectional view of a fourth test structure of an integrated circuit according to an embodiment of the present disclosure;

FIG. 10 is a top view of a fifth test structure of an integrated circuit according to an embodiment of the present disclosure;

FIG. 11 is a cross-sectional view of a fifth test structure of an integrated circuit according to an embodiment of the present disclosure;

FIG. 12 is a top view of a sixth test structure of an integrated circuit according to an embodiment of the present disclosure;

FIG. 13 is a cross-sectional view of a sixth test structure of an integrated circuit according to an embodiment of the present disclosure;

FIG. 14 is a top view of a seventh test structure of an integrated circuit according to an embodiment of the present disclosure; and

FIG. 15 is a cross-sectional view of a seventh test structure of an integrated circuit according to an embodiment of the present disclosure.

### DETAILED DESCRIPTION

To ensure the reliability of the integrated circuit, in the development phase, it is necessary to design the integrated circuit according to electrical parameters of the integrated circuit in the case of a latch-up. Embodiments of the present disclosure provide a test structure of an integrated circuit. The test structure includes a first P-type heavily doped region, a second P-type heavily doped region, and an N-type heavily doped region. There is a first distance between the first P-type heavily doped region and the second P-type heavily doped region, and there is a second distance between the second P-type heavily doped region and the N-type heavily doped region. Different test structures have different first distances and second distances. By adjusting the first distance and/or second distance in each test structure, electrical parameters of an integrated circuit corresponding to the test structure are obtained, thereby providing a basis for the design of the integrated circuit, and improving the reliability of the integrated circuit.

In order to make the objectives, features and advantages of the embodiments of the present disclosure clearer, the technical solutions in the embodiments of the present disclosure are described clearly and completely below with reference to the accompanying drawings in the embodiments of the present disclosure. Apparently, the described embodiments are some rather than all of the embodiments of the present disclosure. All other embodiments obtained by a person of ordinary skill in the art based on the embodiments of the present disclosure without creative efforts should fall within the protection scope of the present disclosure.

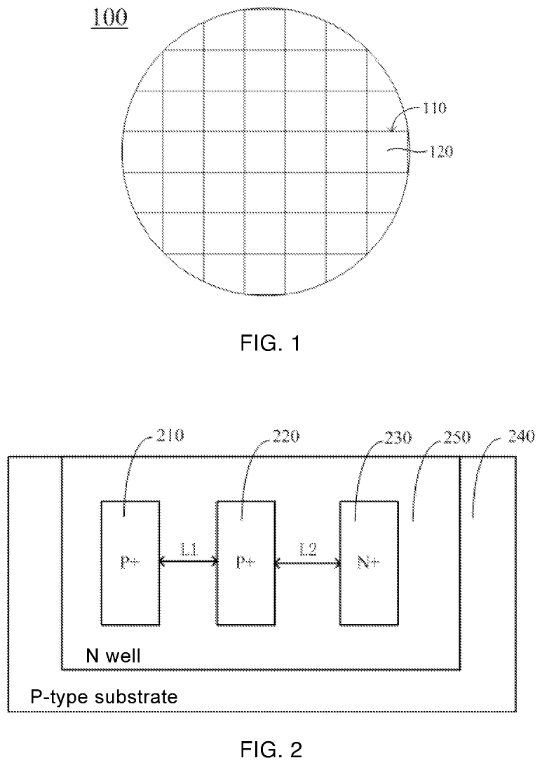

FIG. 1 is a schematic diagram of an application scenario of a test structure of an integrated circuit according to an embodiment of the present disclosure. As shown in FIG. 1, the application scenario of the test structure involves a wafer 100, a plurality of bare dies 120 and scribe lines 110 are formed after the wafer 100 is cut. An integrated circuit is disposed in the bare die 120, and a test structure of the integrated circuit is disposed in the scribe line 110 or the bare die 120. The integrated circuit has the same equivalent circuit as the test structure of the integrated circuit, and electrical parameters of the integrated circuit in the case of a latch-up are tested by testing the test structure of the integrated circuit.

The electrical parameters include a trigger voltage, a holding voltage, a trigger current, and a holding current of the latch-up. The trigger voltage is a voltage when the latch-up occurs, the holding voltage is a voltage for holding the latch-up, the trigger current is a current when the latch-up is triggered, and the holding current is a voltage for holding the latch-up. The trigger voltage is generally higher than the holding voltage. As the trigger voltage or the holding voltage increases, the possibility of the latch-up decreases, i.e., the latch-up is less likely to occur.

The electrical parameters are related to the specific structure of the integrated circuit. The electrical parameters of the integrated circuits are tested by using the test structure of the integrated circuit, and the integrated circuit in the bare die 120 is designed according to a test result, to avoid a latch-up in an operation process of the integrated circuit in the bare die 120, thereby improving the reliability of the integrated circuit. Specifically, the test structure of an integrated circuit may be tested by using a Transmission Line Pulse (TLP), and a design rule of the corresponding integrated circuit can be designed according to the test result, thereby ensuring the reliability of the integrated circuit.

The test structure of an integrated circuit provided in the embodiments of the present disclosure is described in detail. FIG. 2 to FIG. 15 provide seven types of test structures of integrated circuits. In the embodiments below, the heavily doped region is a region in which a large quantity of impurities are doped, that is, a doping concentration is high. The P-type heavily doped region is referred to as P+ for short, and the N-type heavily doped region is referred to as N+ for short. The P-type substrate refers to a P-type semiconductor (positive-type semiconductor) substrate; a depth of the N well is less than that of the deep N well; the depth of the N well is generally 0.3 μm to 0.5 μm, and the depth of the deep N well is generally 0.5 μm to 1 μm.

### Embodiment 1

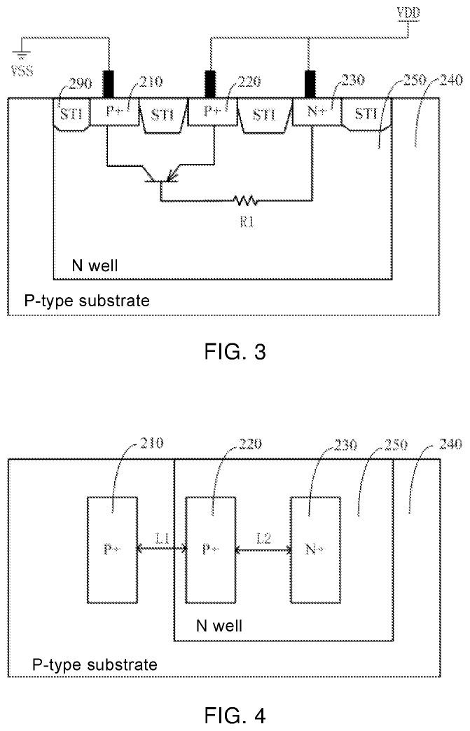

Referring to FIG. 2 and FIG. 3, FIG. 2 is a top view of a first test structure of an integrated circuit according to an embodiment of the present disclosure; FIG. 3 is a cross-sectional view of a first test structure of an integrated circuit according to an embodiment of the present disclosure.

As shown in FIG. 2 and FIG. 3, the test structure of an integrated circuit includes a first P-type heavily doped region 210, a second P-type heavily doped region 220, and an N-type heavily doped region 230. A shallow trench isolation (STI) structure may be arranged between the first P-type heavily doped region 210 and the second P-type heavily doped region 220, and between the second P-type heavily doped region 220 and the N-type heavily doped region 230. The STI structures 290 are filled with an insulation material, to isolate different doped regions, where the STI structure 290 may have a depth of 0.3 μm. The depth of the STI structure 290 refers to a vertical direction in FIG. 3.

The first P-type heavily doped region 210, the second P-type heavily doped region 220, and the N-type heavily doped region 230 are all located in an N well 250, and the N well 250 is located on a P-type substrate 240. As shown in FIG. 2 and FIG. 3, the second P-type heavily doped region 220 is located between the first P-type heavily doped region 210 and the N-type heavily doped region 230.

As shown in FIG. 2, there is a first distance L1 between the first P-type heavily doped region 210 and the second P-type heavily doped region 220, and there is a second distance L2 between the second P-type heavily doped region 220 and the N-type heavily doped region 230. In the test structure of an integrated circuit, electrical parameters of the integrated circuit are obtained by adjusting at least one of the first distance L1 and the second distance L2.

The first P-type heavily doped region 210, the N well 250, and the second P-type heavily doped region 220 form a parasitic PNP transistor. The N well 250 has a parasitic resistor R1. As shown in FIG. 3, the parasitic resistor R1 has a first terminal connected to the N-type heavily doped region 230 and a second terminal connected to a base of the parasitic PNP transistor.

Before the test structure of an integrated circuit in this embodiment of the present disclosure is tested, the test structure needs to be electrically connected. As shown in FIG. 3, the first P-type heavily doped region 210 is connected to a ground terminal VSS, and the second P-type heavily doped region 220 and the N-type heavily doped region 230 are connected to a power terminal VDD.

During the test, a voltage applied to the power terminal VDD is gradually increased from 0V, for example, gradually increased from 0V to 5V, and a current between the power terminal VDD and the ground terminal VSS is monitored. When the current between the power terminal VDD and the ground terminal VSS increases abruptly, it is determined that a latch-up occurs.

By adjusting at least one of the first distance L1 and the second distance L2, a correspondence between multiple sets of the first distances L1 and second distances L2 and the trigger voltages, holding voltages, trigger currents, as well as holding currents of a latch-up is obtained. That is, a correspondence between different first distances L1 as well as second distances L2 and the electrical parameters of the integrated circuit is obtained. The integrated circuit is designed according to the obtained correspondence, to avoid a latch-up in an operation process of the integrated circuit, thereby improving the chip reliability.

In the foregoing test structure of an integrated circuit, the base of the parasitic PNP transistor is the N well 250, and a gain from the base to a collector may be up to dozens of times. In an equivalent circuit formed by the parasitic PNP transistor and the parasitic resistor R1 shown in FIG. 3, the parasitic PNP transistor has an off-state and an on-state. Without an external interference, the parasitic PNP transistor is in the off-state, and the collector has a C-B reverse leakage current. A current gain is very small, which will not cause a latch-up. When the parasitic PNP transistor is triggered by an external interference, and a collector current or voltage thereof increases to a preset value abruptly, the parasitic PNP transistor is turned on. In this case, the parasitic PNP transistor will form a low-impedance path between the power terminal VDD and the ground terminal VSS. An amplified state of the parasitic PNP transistor can be continuously driven with a very small current, thus generating a latch-up.

A test structure of an integrated circuit provided by this embodiment of the present disclosure includes a first P-type heavily doped region 210, a second P-type heavily doped region 220, and an N-type heavily doped region 230, where the first P-type heavily doped region 210, the second P-type heavily doped region 220, and the N-type heavily doped region 230 are all located in an N well 250, and the N well 250 is located on a P-type substrate 240; there is a first distance L1 between the first P-type heavily doped region 210 and the second P-type heavily doped region 220, there is a second distance L2 between the second P-type heavily doped region 220 and the N-type heavily doped region 230, and electrical parameters of the integrated circuit are obtained by adjusting the first distance L1 and/or the second distance L2. The integrated circuit is designed according to a relationship between the first distance L1 and/or second distance L2 and the electrical parameters, to avoid a latch-up in the integrated circuit and improve the reliability of the integrated circuit.

### Embodiment 2

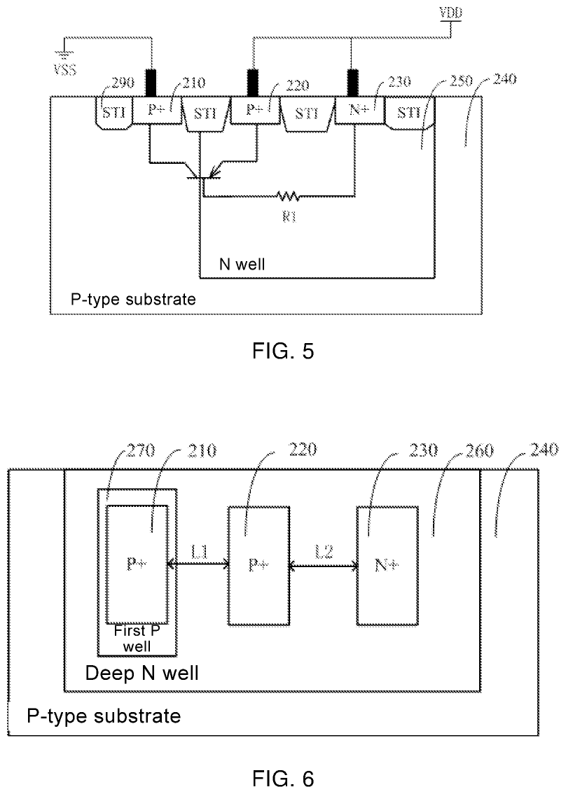

Referring to FIG. 4 and FIG. 5, FIG. 4 is a top view of a second test structure of an integrated circuit according to an embodiment of the present disclosure; FIG. 5 is a cross-sectional view of a second test structure of an integrated circuit according to an embodiment of the present disclosure.

As shown in FIG. 4 and FIG. 5, the test structure of an integrated circuit includes a first P-type heavily doped region 210, a second P-type heavily doped region 220, and an N-type heavily doped region 230. An STI structure 290 is further arranged between the first P-type heavily doped region 210 and the second P-type heavily doped region 220, and between the second P-type heavily doped region 220 and the N-type heavily doped region 230. The STI structures 290 are filled with an insulation material, to isolate different doped regions, where the STI structure 290 may have a depth of 0.3 μm.

The first P-type heavily doped region 210 is located on a P-type substrate 240, the second P-type heavily doped region 220 and the N-type heavily doped region 230 are both located in an N well 250, and the N well 250 is located on the P-type substrate 240. As shown in FIG. 4 and FIG. 5, the second P-type heavily doped region 220 is located between the first P-type heavily doped region 210 and the N-type heavily doped region 230.

As shown in FIG. 4, there is a first distance L1 between the first P-type heavily doped region 210 and the second P-type heavily doped region 220, and there is a second distance L2 between the second P-type heavily doped region 220 and the N-type heavily doped region 230. In the test structure of an integrated circuit, electrical parameters of the integrated circuit are obtained by adjusting the first distance L1 and/or the second distance L2.

The first P-type heavily doped region 210, the N well 250, and the second P-type heavily doped region 220 form a parasitic PNP transistor. The N well 250 has a parasitic resistor R1. As shown in FIG. 4, the parasitic resistor R1 has a first terminal connected to the N-type heavily doped region 230 and a second terminal connected to a base of the parasitic PNP transistor.

Before the test structure of an integrated circuit in this embodiment of the present disclosure is tested, the test structure needs to be electrically connected. As shown in FIG. 5, the first P-type heavily doped region 210 is connected to a ground terminal VSS, and the second P-type heavily doped region 220 and the N-type heavily doped region 230 are connected to a power terminal VDD.

During the test, a voltage applied to the power terminal VDD is gradually increased from 0V, for example, gradually increased from 0V to 5V, and a current between the power terminal VDD and the ground terminal VSS is monitored. When the current between the power terminal VDD and the ground terminal VSS increases abruptly, it is determined that a latch-up occurs.

By adjusting at least one of the first distance L1 and the second distance L2, a correspondence between multiple sets of the first distances L1 and second distances L2 and the trigger voltages, holding voltages, trigger currents, as well as holding currents of a latch-up is obtained. That is, a correspondence between different first distances L1 as well as second distances L2 and the electrical parameters of the integrated circuit is obtained. The integrated circuit is designed according to the obtained correspondence, to avoid a latch-up in an operation process of the integrated circuit, thereby improving the chip reliability.

In the foregoing test structure of an integrated circuit, the base of the parasitic PNP transistor is the N well 250, and a gain from the base to a collector may be up to dozens of times. In an equivalent circuit formed by the parasitic PNP transistor and the parasitic resistor R1 shown in FIG. 5, the parasitic PNP transistor has an off-state and an on-state. Without an external interference, the parasitic PNP transistor is in the off-state, and the collector has a C-B reverse leakage current. A current gain is very small, which will not cause a latch-up. When the parasitic PNP transistor is triggered by an external interference, and a collector current or voltage thereof increases to a preset value abruptly, the parasitic PNP transistor is turned on. In this case, the parasitic PNP transistor will form a low-impedance path between the power terminal VDD and the ground terminal VSS. An amplified state of the parasitic PNP transistor can be continuously driven with a very small current, thus generating a latch-up.

This embodiment of the present disclosure provides a test structure of an integrated circuit, including: a first P-type heavily doped region 210, a second P-type heavily doped region 220, and an N-type heavily doped region 230, where the first P-type heavily doped region 210 is located on a P-type substrate 240, the second P-type heavily doped region 220 and the N-type heavily doped region 230 are both located in an N well 250, and the N well 250 is located on the P-type substrate 240; there is a first distance between the first P-type heavily doped region 210 and the second P-type heavily doped region 220, there is a second distance between the second P-type heavily doped region 220 and the N-type heavily doped region 230, and electrical parameters of the integrated circuit are obtained by adjusting the first distance and/or the second distance. Distances in the integrated circuit are designed according to a relationship between the first distance and/or second distance and the electrical parameters, to avoid a latch-up in the integrated circuit and improve the reliability of the integrated circuit.

### Embodiment 3

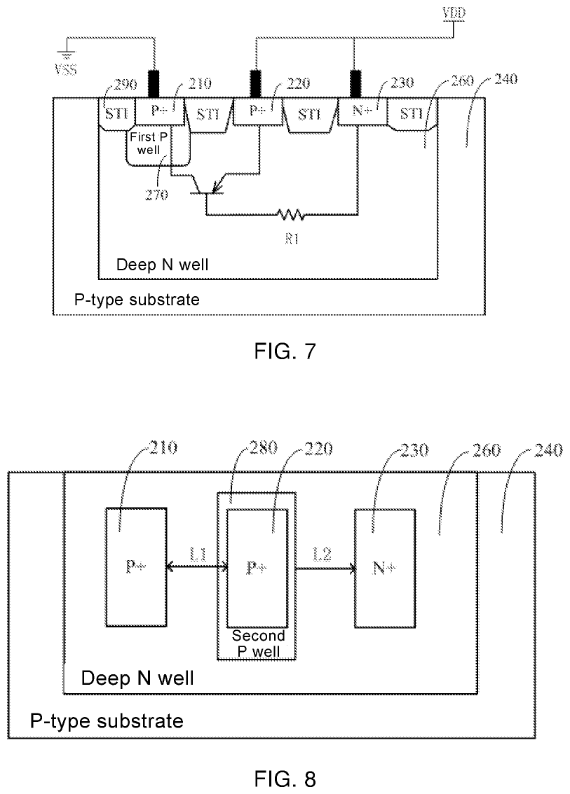

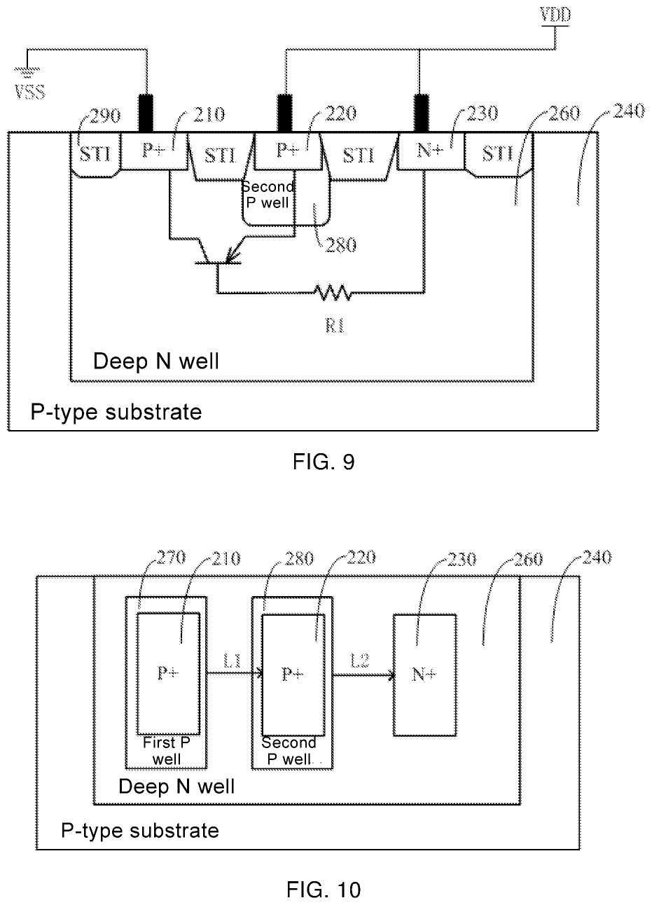

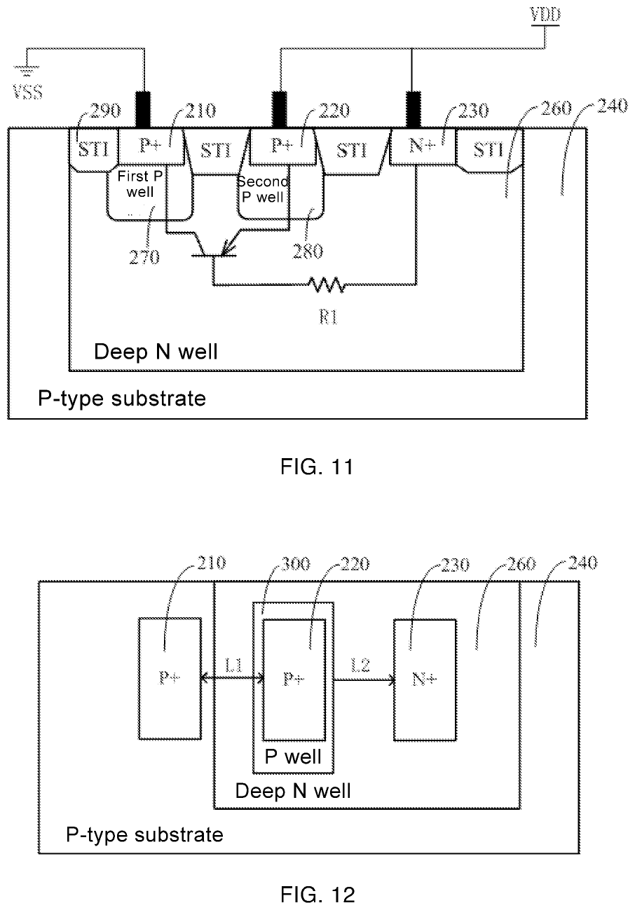

As shown in FIG. 6 to FIG. 11, FIG. 6 is a top view of a third test structure of an integrated circuit according to an embodiment of the present disclosure; FIG. 7 is a cross-sectional view of a third test structure of an integrated circuit according to an embodiment of the present disclosure; FIG. 8 is a top view of a fourth test structure of an integrated circuit according to an embodiment of the present disclosure; FIG. 9 is a cross-sectional view of a fourth test structure of an integrated circuit according to an embodiment of the present disclosure; FIG. 10 is a top view of a fifth test structure of an integrated circuit according to an embodiment of the present disclosure; and FIG. 11 is a cross-sectional view of a fifth test structure of an integrated circuit according to an embodiment of the present disclosure.

The test structure of an integrated circuit includes a first P-type heavily doped region 210, a second P-type heavily doped region 220, and an N-type heavily doped region 230. An STI structure 290 is further arranged between the first P-type heavily doped region 210 and the second P-type heavily doped region 220, and between the second P-type heavily doped region 220 and the N-type heavily doped region 230. The STI structures 290 are filled with an insulation material, to isolate different doped regions, where the STI structure 290 may have a depth of 0.3 μm.

The first P-type heavily doped region 210, the second P-type heavily doped region 220, and the N-type heavily doped region 230 are located in a deep N well 260 that is located on a P-type substrate 240, and the first P-type heavily doped region 210 is located in a first P well 270 that is located in the deep N well 260; and/or the second P-type heavily doped region 220 is located in a second P well 280, and the second P well 280 is located in the deep N well 260.

As shown in FIG. 6 to FIG. 11, the second P-type heavily doped region 220 may be located in the first P-type heavily doped region 210 and the N-type heavily doped region 230, there is a first distance L1 between the first P-type heavily doped region 210 and the second P-type heavily doped region 220, and there is a second distance L2 between the second P-type heavily doped region 220 and the N-type heavily doped region 230. In the test structure of an integrated circuit, electrical parameters of the integrated circuit are obtained by adjusting the first distance L1 and/or the second distance L2.

In a first possible example, as shown in FIG. 6 and FIG. 7, the second P-type heavily doped region 220 is located in a deep N well 260, and the first P-type heavily doped region 210 is located in a first P well 270. That is, the N-type heavily doped region 230 and the second P-type heavily doped region 220 are both located in the deep N well 260 that is located on the P-type substrate 240, and the first P-type heavily doped region 210 is located in the first P well 270 that is located in the deep N well 260.

As shown in FIG. 7, the first P well 270, the deep N well 260, and the second P-type heavily doped region 220 form a parasitic PNP transistor. The deep N well 260 has a parasitic resistor R1, and the parasitic resistor R1 has a first terminal connected to the N-type heavily doped region 230 and a second terminal connected to a base of the parasitic PNP transistor.

In a second possible example, as shown in FIG. 8 and FIG. 9, the first P-type heavily doped region 210 is located in a deep N well 260, and the second P-type heavily doped region 220 is located in a second P well 280. That is, the N-type heavily doped region 230 and the first P-type heavily doped region 210 are both located in the deep N well 260 that is located on a P-type substrate 240, and the second P-type heavily doped region 220 is located in the second P well 280 that is located in the deep N well 260.

As shown in FIG. 9, the first P-type heavily doped region 210, the deep N well 260, and the second P well 280 form a parasitic PNP transistor. The deep N well 260 has a parasitic resistor R1, and the parasitic resistor R1 has a first terminal connected to the N-type heavily doped region 230 and a second terminal connected to a base of the parasitic PNP transistor.

In a third possible example, as shown in FIG. 10 and FIG. 11, the first P-type heavily doped region 210 is located in a first P well 270, and the second P-type heavily region is located in a second P well 280. That is, the N-type heavily doped region 230 is located in a deep N well 260 that is located on a P-type substrate 240, the first P-type heavily doped region 210 is located in the first P well 270, the second P-type heavily doped region is located in the second P well 280, and the first P well 270 and the second P well 280 are both located in the deep N well 260.

As shown in FIG. 11, the first P well 270, the deep N well 260, and the second P well 280 form a parasitic PNP transistor. The deep N well 260 has a parasitic resistor R1, and the parasitic resistor R1 has a first terminal connected to the N-type heavily doped region 230 and a second terminal connected to a base of the parasitic PNP transistor.

Before the test structure of an integrated circuit in the foregoing three examples is tested, the test structure needs to be electrically connected. Specifically, as shown in FIG. 7, FIG. 9 and FIG. 11, the first P-type heavily doped region 210 is connected to a ground terminal VSS, and the second P-type heavily doped region 220 and the N-type heavily doped region 230 are connected to a power terminal VDD.

During the test, a voltage applied to the power terminal VDD is gradually increased from 0V, for example, gradually increased from 0V to 5V, and a current between the power terminal VDD and the ground terminal VSS is monitored. When the current between the power terminal VDD and the ground terminal VSS increases abruptly, it is determined that a latch-up occurs.

By adjusting at least one of the first distance L1 and the second distance L2, a correspondence between multiple sets of the first distances L1 and second distances L2 and the trigger voltages, holding voltages, trigger currents, as well as holding currents of a latch-up is obtained. That is, a correspondence between different first distances L1 as well as second distances L2 and the electrical parameters of the integrated circuit is obtained. The integrated circuit is designed according to the obtained correspondence, to avoid a latch-up in an operation process of the integrated circuit, thereby improving the chip reliability.

In the foregoing test structure of an integrated circuit, the base of the parasitic PNP transistor is the deep N well 260, and a gain from the base to a collector may be up to dozens of times. In an equivalent circuit formed by the parasitic PNP transistor and the parasitic resistor R1 shown in FIG. 7, FIG. 9 and FIG. 11, the parasitic PNP transistor has an off-state and an on-state. Without an external interference, the parasitic PNP transistor is in the off-state, and the collector has a C-B reverse leakage current. A current gain is very small, which will not cause a latch-up. When the parasitic PNP transistor is triggered by an external interference, and a collector current or voltage thereof increases to a preset value abruptly, the parasitic PNP transistor is turned on. In this case, the parasitic PNP transistor will form a low-impedance path between the power terminal VDD and the ground terminal VSS. An amplified state of the parasitic PNP transistor can be continuously driven with a very small current, thus generating a latch-up.

This embodiment of the present disclosure provides a test structure of an integrated circuit, including a first P-type heavily doped region 210, a second P-type heavily doped region 220, and an N-type heavily doped region 230, which are all located in a deep N well 260, where the deep N well 260 is located on a P-type substrate 240, the first P-type heavily doped region 210 is located in a first P well 270, and the first P well 270 is located in the deep N well 260; and/or the second P-type heavily doped region 220 is located in a second P well 280, and the second P well 280 is located in the deep N well 260. There is a first distance L1 between the first P-type heavily doped region 210 and the second P-type heavily doped region 220, there is a second distance L2 between the second P-type heavily doped region 220 and the N-type heavily doped region 230, and electrical parameters of the integrated circuit are obtained by adjusting the first distance L1 and/or the second distance L2. Distances in the integrated circuit are set according to a relationship between the first distance L1 and/or second distance L2 and the electrical parameters, to avoid a latch-up in the integrated circuit and improve the reliability of the integrated circuit.

### Embodiment 4

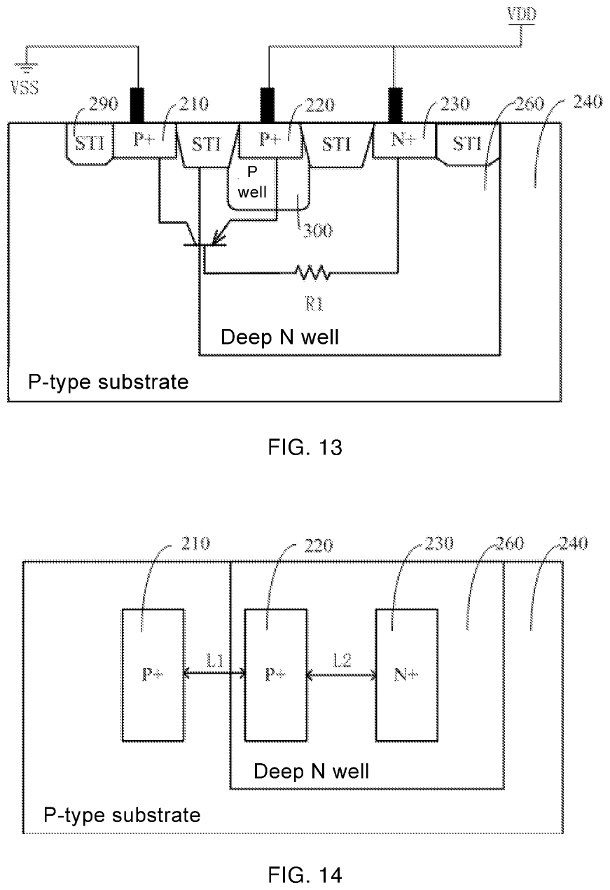

Referring to FIG. 12 and FIG. 13, FIG. 12 is a top view of a sixth test structure of an integrated circuit according to an embodiment of the present disclosure; FIG. 13 is a cross-sectional view of a sixth test structure of an integrated circuit according to an embodiment of the present disclosure.

As shown in FIG. 12 and FIG. 13, the test structure of an integrated circuit includes a first P-type heavily doped region 210, a second P-type heavily doped region 220, and an N-type heavily doped region 230. An STI structure 290 is further arranged between the first P-type heavily doped region 210 and the second P-type heavily doped region 220, and between the second P-type heavily doped region 220 and the N-type heavily doped region 230. The STI structures 290 are filled with an insulation material, to isolate different doped regions, where the STI structure 290 may have a depth of 0.3 μm.

The first P-type heavily doped region 210 is located on a P-type substrate 240, the second P-type heavily doped region 220 is located in a P well 300 that is located in a deep N well 260, the N-type heavily doped region 230 is located in the deep N well 260, and the deep N well 260 is located on the P-type substrate 240. As shown in FIG. 12 and FIG. 13, the second P-type heavily doped region 220 is located between the first P-type heavily doped region 210 and the N-type heavily doped region 230.

As shown in FIG. 12, there is a first distance L1 between the first P-type heavily doped region 210 and the second P-type heavily doped region 220, and there is a second distance L2 between the second P-type heavily doped region 220 and the N-type heavily doped region 230. In the test structure of an integrated circuit, electrical parameters of the integrated circuit are obtained by adjusting the first distance L1 and/or the second distance L2.

The first P-type heavily doped region 210, the deep N well 260, and the P well 300 form a parasitic PNP transistor. The deep N well 260 has a parasitic resistor R1, and the parasitic resistor R1 has a first terminal connected to the N-type heavily doped region 230 and a second terminal connected to a base of the parasitic PNP transistor.

Before the test structure of an integrated circuit in this embodiment of the present disclosure is tested, the test structure needs to be electrically connected. As shown in FIG. 13, the first P-type heavily doped region 210 is connected to a ground terminal VSS, and the second P-type heavily doped region 220 and the N-type heavily doped region 230 are connected to a power terminal VDD.

During the test, a voltage applied to the power terminal VDD is gradually increased from 0V, for example, gradually increased from 0V to 5V, and a current between the power terminal VDD and the ground terminal VSS is monitored. When the current between the power terminal VDD and the ground terminal VSS increases abruptly, it is determined that a latch-up occurs.

By adjusting at least one of the first distance L1 and the second distance L2, a correspondence between multiple sets of the first distances L1 and second distances L2 and the trigger voltages, holding voltages, trigger currents, as well as holding currents of a latch-up is obtained. That is, a correspondence between different first distances L1 as well as second distances L2 and the electrical parameters of the integrated circuit is obtained. The integrated circuit is designed according to the obtained correspondence, to avoid a latch-up in an operation process of the integrated circuit, thereby improving the chip reliability.

In the foregoing test structure of an integrated circuit, the base of the parasitic PNP transistor is the deep N well 260, and a gain from the base to a collector may be up to dozens of times. In an equivalent circuit formed by the parasitic PNP transistor and the parasitic resistor R1 shown in FIG. 13, the parasitic PNP transistor has an off-state and an on-state. Without an external interference, the parasitic PNP transistor is in the off-state, and the collector has a C-B reverse leakage current. A current gain is very small, which will not cause a latch-up. When the parasitic PNP transistor is triggered by an external interference, and a collector current or voltage thereof increases to a preset value abruptly, the parasitic PNP transistor is turned on. In this case, the parasitic PNP transistor will form a low-impedance path between the power terminal VDD and the ground terminal VSS. An amplified state of the parasitic PNP transistor can be continuously driven with a very small current, thus generating a latch-up.

This embodiment of the present disclosure provides a test structure of an integrated circuit, including a first P-type heavily doped region 210, a second P-type heavily doped region 220, and an N-type heavily doped region 230, where the first P-type heavily doped region 210 is located on a P-type substrate 240, the second P-type heavily doped region 220 is located in a P well 300 that is located in a deep N well 260, the N-type heavily doped region 230 is located in the deep N well 260, and the deep N well 260 is located on the P-type substrate 240; there is a first distance L1 between the first P-type heavily doped region 210 and the second P-type heavily doped region 220, there is a second distance L2 between the second P-type heavily doped region 220 and the N-type heavily doped region 230, and electrical parameters of the integrated circuit are obtained by adjusting the first distance L1 and/or the second distance L2. Distances in the integrated circuit are set according to a relationship between the first distance L1 and/or second distance L2 and the electrical parameters, to avoid a latch-up in the integrated circuit and improve the reliability of the integrated circuit.

### Embodiment 5

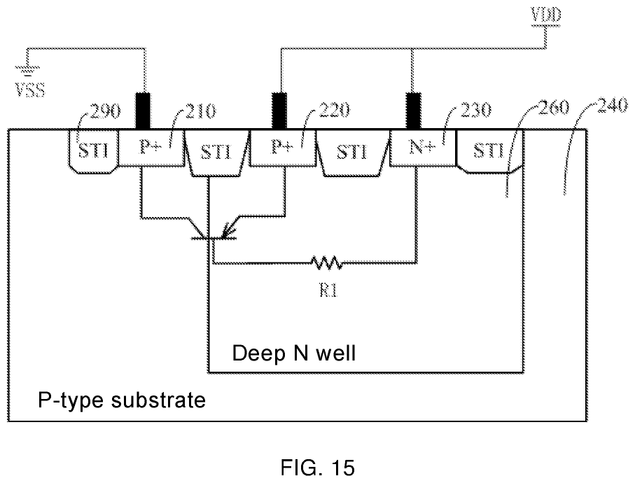

Referring to FIG. 14 and FIG. 15, FIG. 14 is a top view of a seventh test structure of an integrated circuit according to an embodiment of the present disclosure; FIG. 15 is a cross-sectional view of a seventh test structure of an integrated circuit according to an embodiment of the present disclosure.

As shown in FIG. 14 and FIG. 15, the test structure includes a first P-type heavily doped region 210, a second P-type heavily doped region 220, and an N-type heavily doped region 230. An STI structure 290 may be further arranged between the first P-type heavily doped region 210 and the second P-type heavily doped region 220, and between the second P-type heavily doped region 220 and the N-type heavily doped region 230. The STI structures 290 are filled with an insulation material, to isolate different doped regions, where the STI structure 290 may have a depth of 0.3 μm.

The first P-type heavily doped region 210 is located on a P-type substrate 240, the N-type heavily doped region 230 and the second P-type heavily doped region 220 are both located in a deep N well 260, and the deep N well 260 is located on the P-type substrate 240. For example, the second P-type heavily doped region 220 is located between the first P-type heavily doped region 210 and the N-type heavily doped region 230.

As shown in FIG. 14, there is a first distance L1 between the first P-type heavily doped region 210 and the second P-type heavily doped region 220, and there is a second distance L2 between the second P-type heavily doped region 220 and the N-type heavily doped region 230. In the test structure of an integrated circuit, electrical parameters of the integrated circuit are obtained by adjusting the first distance L1 and/or the second distance L2.

The first P-type heavily doped region 210, the deep N well 260, and the second P-type heavily doped region 220 form a parasitic PNP transistor. The N well 250 has a parasitic resistor R1. As shown in FIG. 15, the parasitic resistor R1 has a first terminal connected to the N-type heavily doped region 230 and a second terminal connected to a base of the parasitic PNP transistor.

Before the test structure of an integrated circuit in this embodiment of the present disclosure is tested, the test structure needs to be electrically connected. As shown in FIG. 15, the first P-type heavily doped region 210 is connected to a ground terminal VSS, and the second P-type heavily doped region 220 and the N-type heavily doped region 230 are connected to a power terminal VDD.

During the test, a voltage applied to the power terminal VDD is gradually increased from 0V, for example, gradually increased from 0V to 5V, and a current between the power terminal VDD and the ground terminal VSS is monitored. When the current between the power terminal VDD and the ground terminal VSS increases abruptly, it is determined that a latch-up occurs.

By adjusting at least one of the first distance L1 and the second distance L2, a correspondence between multiple sets of the first distances L1 and second distances L2 and the trigger voltages, holding voltages, trigger currents, as well as holding currents of a latch-up is obtained. That is, a correspondence between different first distances L1 as well as second distances L2 and the electrical parameters of the integrated circuit is obtained. The integrated circuit is designed according to the obtained correspondence, to avoid a latch-up in an operation process of the integrated circuit, thereby improving the chip reliability.

In the foregoing test structure of an integrated circuit, the base of the parasitic PNP transistor is the deep N well 260, and a gain from the base to a collector may be up to dozens of times. In an equivalent circuit formed by the parasitic PNP transistor and the parasitic resistor R1 shown in FIG. 15, the parasitic PNP transistor has an off-state and an on-state. Without an external interference, the parasitic PNP transistor is in the off-state, and the collector has a C-B reverse leakage current. A current gain is very small, which will not cause a latch-up. When the parasitic PNP transistor is triggered by an external interference, and a collector current or voltage thereof increases to a preset value abruptly, the parasitic PNP transistor is turned on. In this case, the parasitic PNP transistor will form a low-impedance path between the power terminal VDD and the ground terminal VSS. An amplified state of the parasitic PNP transistor can be continuously driven with a very small current, thus generating a latch-up.

This embodiment of the present disclosure provides a test structure of an integrated circuit, including a first P-type heavily doped region 210, a second P-type heavily doped region 220, and an N-type heavily doped region 230, where the first P-type heavily doped region 210 is located on a P-type substrate 240, the N-type heavily doped region 230 and the second P-type heavily doped region 220 are located in a deep N well 260, and the deep N well 260 is located on the P-type substrate 240; there is a first distance L1 between the first P-type heavily doped region 210 and the second P-type heavily doped region 220, there is a second distance L2 between the second P-type heavily doped region 220 and the N-type heavily doped region 230, and electrical parameters of the integrated circuit are obtained by adjusting the first distance L1 and/or the second distance L2. Distances in the integrated circuit are set according to a relationship between the first distance L1 and/or second distance L2 and the electrical parameters, to avoid a latch-up in the integrated circuit and improve the reliability of the integrated circuit.

This embodiment of the present disclosure provides a test structure of an integrated circuit. Distances in the integrated circuit are set according to a relationship between the first distance and/or second distance and the electrical parameters, to avoid a latch-up in the integrated circuit and improve the reliability of the integrated circuit.

The embodiments or implementations of this specification are described in a progressive manner, and each embodiment focuses on differences from other embodiments. The same or similar parts between the embodiments may refer to each other.

In the descriptions of this specification, a description with reference to the term “one implementation”, “some implementations”, “an exemplary implementation”, “an example”, “a specific example”, “some examples”, or the like means that a specific feature, structure, material, or characteristic described in combination with the implementation(s) or example(s) is included in at least one implementation or example of the present disclosure. In this specification, the schematic expression of the above terms does not necessarily refer to the same implementation or example. Moreover, the described specific feature, structure, material or characteristic may be combined in an appropriate manner in any one or more implementations or examples.

Finally, it should be noted that the foregoing embodiments are used only to explain the technical solutions of the present disclosure, but are not intended to limit the present disclosure. Although the present disclosure has been described in detail with reference to the foregoing embodiments, those of ordinary skill in the art should understand that they can still modify the technical solutions described in the foregoing embodiments, or make equivalent substitutions on some or all technical features therein. The modifications or substitutions do not make the essence of the corresponding technical solutions deviate from the spirit and scope of the technical solutions of the embodiments of the present disclosure.

1. A test structure of an integrated circuit, comprising: a first P-type heavily doped region, a second P-type heavily doped region, and an N-type heavily doped region, wherein
the first P-type heavily doped region, the second P-type heavily doped region, and the N-type heavily doped region are all located in an N well, and the N well is located on a P-type substrate; or, the first P-type heavily doped region is located on a P-type substrate, the second P-type heavily doped region and the N-type heavily doped region are both located in an N well, and the N well are located on the P-type substrate; and
there is a first distance between the first P-type heavily doped region and the second P-type heavily doped region, there is a second distance between the second P-type heavily doped region and the N-type heavily doped region, and electrical parameters of the integrated circuit are obtained by adjusting at least one of the first distance or the second distance.

2. The test structure of an integrated circuit according to claim 1, wherein the first P-type heavily doped region, the second P-type heavily doped region, and the N-type heavily doped region are all located in the N well, and the N well is located on the P-type substrate;
the second P-type heavily doped region is located between the first P-type heavily doped region and the N-type heavily doped region; and
the first P-type heavily doped region, the N well and the second P-type heavily doped region form a parasitic PNP transistor.

3. The test structure of an integrated circuit according to claim 2, wherein the N well has a parasitic resistor, and the parasitic resistor has a first terminal connected to the N-type heavily doped region and a second terminal connected to a base of the parasitic PNP transistor.

4. The test structure of an integrated circuit according to claim 1, wherein the first P-type heavily doped region is located on the P-type substrate, the second P-type heavily doped region and the N-type heavily doped region are both located in the N well, and the N well are located on the P-type substrate;
the second P-type heavily doped region is located between the first P-type heavily doped region and the N-type heavily doped region; and
the first P-type heavily doped region, the N well and the second P-type heavily doped region form a parasitic PNP transistor.

5. The test structure of an integrated circuit according to claim 4, wherein the N well has a parasitic resistor, and the parasitic resistor has a first terminal connected to the N-type heavily doped region and a second terminal connected to a base of the parasitic PNP transistor.

6. A test structure of an integrated circuit, comprising: a first P-type heavily doped region, a second P-type heavily doped region, and an N-type heavily doped region, wherein
the first P-type heavily doped region, the second P-type heavily doped region, and the N-type heavily doped region are all located in a deep N well, and the deep N well is located on a P-type substrate;
at least one of the first P-type heavily doped region is located in a first P well, and the first P well is located in the deep N well; or, the second P-type heavily doped region is located in a second P well, and the second P well is located in the deep N well; and
there is a first distance between the first P-type heavily doped region and the second P-type heavily doped region, there is a second distance between the second P-type heavily doped region and the N-type heavily doped region, and electrical parameters of the integrated circuit are obtained by adjusting at least one of the first distance or the second distance.

7. The test structure of an integrated circuit according to claim 6, wherein the second P-type heavily doped region is located in the deep N well, and the first P-type heavily doped region is located in the first P well;
the second P-type heavily doped region is located between the first P-type heavily doped region and the N-type heavily doped region; and
the first P well, the deep N well, and the second P-type heavily doped region form a parasitic PNP transistor.

8. The test structure of an integrated circuit according to claim 7, wherein the deep N well has a parasitic resistor, and the parasitic resistor has a first terminal connected to the N-type heavily doped region and a second terminal connected to a base of the parasitic PNP transistor.

9. The test structure of an integrated circuit according to claim 6, wherein the first P-type heavily doped region is located in the deep N well, and the second P-type heavily doped region is located in the second P well;
the second P-type heavily doped region is located between the first P-type heavily doped region and the N-type heavily doped region; and
the first P-type heavily doped region, the deep N well, and the second P well form a parasitic PNP transistor.

10. The test structure of an integrated circuit according to claim 9, wherein the deep N well has a parasitic resistor, and the parasitic resistor has a first terminal connected to the N-type heavily doped region and a second terminal connected to a base of the parasitic PNP transistor.

11. The test structure of an integrated circuit according to claim 6, wherein the first P-type heavily doped region is located in the first P well, and the second P-type heavily doped region is located in the second P well;
the second P-type heavily doped region is located between the first P-type heavily doped region and the N-type heavily doped region; and
the first P well, the deep N well, and the second P well form a parasitic PNP transistor.

12. The test structure of an integrated circuit according to claim 11, wherein the deep N well has a parasitic resistor, and the parasitic resistor has a first terminal connected to the N-type heavily doped region and a second terminal connected to a base of the parasitic PNP transistor.

13. A test structure of an integrated circuit, comprising: a first P-type heavily doped region, a second P-type heavily doped region, and an N-type heavily doped region, wherein
the first P-type heavily doped region is located on a P-type substrate, the second P-type heavily doped region is located in a P well that is located in a deep N well, and the N-type heavily doped region is located in the deep N well that is located on the P-type substrate; or, the first P-type heavily doped region is located on a P-type substrate, the second P-type heavily doped region and the N-type heavily doped region are both located in a deep N well, and the deep N well is located on the P-type substrate; and
there is a first distance between the first P-type heavily doped region and the second P-type heavily doped region, there is a second distance between the second P-type heavily doped region and the N-type heavily doped region, and electrical parameters of the integrated circuit are obtained by adjusting at least one of the first distance or the second distance.

14. The test structure of an integrated circuit according to claim 13, wherein the first P-type heavily doped region is located on the P-type substrate, the second P-type heavily doped region is located in the P well that is located in the deep N well, and the N-type heavily doped region is located in the deep N well that is located on the P-type substrate;
the second P-type heavily doped region is located between the first P-type heavily doped region and the N-type heavily doped region; and
the first P-type heavily doped region, the deep N well, and the P well form a parasitic PNP transistor.

15. The test structure of an integrated circuit according to claim 14, wherein the deep N well has a parasitic resistor, and the parasitic resistor has a first terminal connected to the N-type heavily doped region and a second terminal connected to a base of the parasitic PNP transistor.

16. The test structure of an integrated circuit according to claim 13, wherein the first P-type heavily doped region is located on the P-type substrate, the second P-type heavily doped region and the N-type heavily doped region are both located in the deep N well, and the deep N well is located on the P-type substrate;
the second P-type heavily doped region is located between the first P-type heavily doped region and the N-type heavily doped region; and
the first P-type heavily doped region, the deep N well, and the second P-type heavily doped region form a parasitic PNP transistor.

17. The test structure of an integrated circuit according to claim 16, wherein the deep N well has a parasitic resistor, and the parasitic resistor has a first terminal connected to the N-type heavily doped region and a second terminal connected to a base of the parasitic PNP transistor.
